(19) United States
(12) Patent Application Publication
(10) Pub. No.: US 2013/0284922 A1
(43) Pub. Date: Oct. 31, 2013

(54) Charged-Particle Beam Apparatus Having Micro Scale Management Function

(71) Applicants: Keisuke Mikami, Mito (JP); Mitsugu Kitazawa, Mito (JP)

(72) Inventors: Keisuke Mikami, Mito (JP); Mitsugu Kitazawa, Mito (JP)

(73) Assignee: HITACHI HIGH-TECHNOLOGIES CORPORATION, Tokyo (JP)

(21) Appl. No.: 13/976,473

(22) PCT Filed: Oct. 11, 2011
(86) PCT No.: PCT/JP2011/005672

§ 371 Date: Jun. 27, 2013

(30) Foreign Application Priority Data
Dec. 28, 2010 (JP) 2010291541

(51) Int. Cl. H01J 37/26

(52) U.S. Cl. CPC H01J 37/261
USPC 250/310

(57) ABSTRACT

There is implemented a scanning electron microscope or a charged-particle beam apparatus. The scanning electron microscope or the charged-particle beam apparatus is provided with a function capable of managing utilization states of a micro scale with ease. The utilization states include a radiation position and the number of utilizations. A map corresponding to the layout of cells on the micro cells is created. The apparatus user selects a cell on the micro scale as a cell to be actually used from cells displayed on the map. On the actual display, the number of utilizations is not displayed simply as numerical data. Instead, cells are displayed on the map in different colors each indicating a utilization state. In addition, the utilization states of the micro scale are classified properly into categories and each of the colors is assigned to one of the categories.

### TECHNICAL FIELD

The present invention relates to a charged-particle beam apparatus and a dimension calibration standard sample (referred to hereafter as a micro scale). More specifically, the present invention relates to a charged-particle beam apparatus making use of such a micro scale as a calibration sample.

### BACKGROUND ART

Dimensions of a pattern on a semiconductor wafer of recent years are required to have fabrication precision of 100 nm or smaller and management of dimensions of line patterns becomes important. For length measurements of dimensions of line patterns, an apparatus making use of a charged-particle beam apparatus referred to as a scanning electron microscope (SEM) is used. In particular, a CD-SEM is widely used. The CD-SEM is a scanning electron microscope specialized for applications such as length measurements of dimensions of semiconductor line patterns or length measurements of hole diameters of contact holes. There are a variety of needs in the apparatus-performance field. However, it is possible to improve mainly the resolution (high magnifying-power observation), the repeated length measurement precision (reproducibility) and the dimension calibration precision. The dimension calibration precision is required to be precision of 1 nm or smaller and a micro scale is used as a dimension calibration sample. The micro scale is normally a sample made by creating an uneven pattern having a diffractive grating shape on a silicon substrate. In recent years, an uneven pattern having a pitch size of about 100 nm has appeared on the scene.

A typical invention of such a dimension calibration sample is described in documents such as patent document 1. This reference discloses a micro scale having a structure in which an alignment pattern having a cross-mark shape is placed around a rectangular area (referred to as a cell). In the rectangular area, a grating pattern of lines and spaces used for dimension calibration is created. In the case of a micro scale having a pitch size of about 100 nm, the number of cells created on one micro scale is several hundreds in the lateral direction and several hundreds in the longitudinal direction. That is to say, the number of cells is at least 10,000. The number of cells is thus very big.

### PRIOR ART LITERATURE

### Patent Document

### Patent Document 1:

JP-2006-10522-A (U.S. Pat. No. 7,361,898)

### SUMMARY OF THE INVENTION

### Problems to be Solved by the Invention

Normally, the micro scale is made by creating an uneven pattern having a diffractive grating shape on a silicon substrate so that the micro scale exhibits commensurate endurance against radiation of an electron beam. If an electron beam is radiated too much to the silicon substrate, however, the pattern is burnt and/or the unevenness is damaged even if the substrate is made of silicon. Thus, correct dimension calibration cannot be carried out. In consequence, it is necessary to properly manage the use of uneven patterns on the micro scale.

In the past, the number of micro-scale utilizations was managed on the basis of simple utilization-count management. That is to say, in accordance with a method adopted in the past, the number of utilizations of a certain cell on a micro scale is determined in advance and, as the number of utilizations exceeds a set value, the operation is shifted to a cell adjacent to the certain cell in order to start the use of the adjacent cell. In accordance with this method, information on positions of cells in a coordinate system for controlling the movement of a stage is measured in advance. (In this case, the information on positions of cells is typically information on positions of the centers of the cells). Then, the number of electron beam radiations to each of the positions of the cells is counted. As the count exceeds a set value, the coordinates of the position of the used cell are changed in accordance with a length measurement recipe.

However, the semiconductor circuit pattern becomes finer and finer. Thus, in the future, the line pattern pitch of the dimension calibration standard sample is predicted to further become finer and finer too. With the conventional method, information on the position of a cell existing on the micro scale to serve as a cell to be used next is supplied manually so that it is quite within the bounds of possibility that the information on the position of such a cell is supplied mistakenly due to a human error.

In addition, the need for a length measurement of a line pattern exists not only for the CD-SEM, but also for a general-purpose scanning electron microscope (a general-purpose SEM). However, the general-purpose SEM does not have an apparatus-specific function. To be more specific, the general-purpose SEM does not have a length-measurement-recipe setting function.

It is thus an object of the present invention to implement a scanning electron microscope (or a charged-particle beam apparatus) having a function capable of simply managing the utilization states of a micro scale such as the radiation positions of the micro scale and the utilization count of the micro scale.

### Means for Solving the Problems

In accordance with the present invention, in order to achieve the object described above, a map showing the layout of cells on the micro scale is created and the utilization states of the cells are displayed on the map. The apparatus user selects a cell existing on the micro scale to serve as a cell to be actually used from the cells displayed on the map. When displaying cells, a number is not merely displayed to indicate a utilization count. Instead, the cells on the map are displayed in different colors according to utilization states. In addition, the utilization states of the micro scale are classified into proper categories and the classification categories are displayed in different colors.

### Effects of the Invention

In accordance with the present invention, the utilization states of cells on a micro scale having a configuration including a large number of aforementioned cells can be verified visually. Thus, it is possible to reduce the number of operations to mistakenly select a cell in a dimension calibration work. Accordingly, with regard to the management of the utilizations of the micro scale, systematic management can be provided from human management so that it is possible to improve the length measurement precision (reproducibility) and the dimension calibration precision.

### BRIEF DESCRIPTION OF THE DRAWINGS

FIG. 1 is an explanatory diagram showing the entire configuration of a scanning electron microscope;

FIG. 2 is explanatory diagrams showing the configuration of a micro scale;

FIG. 3 is diagrams each showing a map for micro scale management;

FIG. 4 is a diagram showing a typical GUI displaying a micro scale management screen;

FIG. 5(a) is a diagram showing a typical taken SEM image and a typical length measurement profile;

FIG. 5(b) is a diagram showing a standard profile and a typical profile of a damaged cell;

FIG. 5(c) shows a typical cumulative time management table;

FIG. 5(d) shows a typical observation condition table;

FIG. 6(a) is a model diagram showing a relation between the magnifying power and the FOV size;

FIG. 6(b) shows a typical configuration of a management table of radiation areas;

FIG. 6(c) is a diagram showing utilization states of cells displayed on a GUI;

FIG. 7 is diagrams to be referred to in explanation of a management method making use of length measurement of each magnifying power and a plurality of utilizations; and

FIG. 8 is a diagram to be referred to in explanation of an operation to color a measurement length area by making use of an SEM image (a used cell).

### MODE FOR CARRYING OUT THE INVENTION

Embodiments of the present invention are explained by referring to diagrams as follows. It is to be noted that a typical charged-particle beam apparatus is exemplified by taking a scanning electron microscope (referred to hereafter as an SEM) as an example. However, the present invention can also be applied to general charged-particle beam apparatus that can be used in measurements, inspections and fabrications. Examples of such charged-particle beam apparatus are an external-appearance inspecting apparatus making use of an electron beam, a converged ion beam apparatus and an ion microscope.

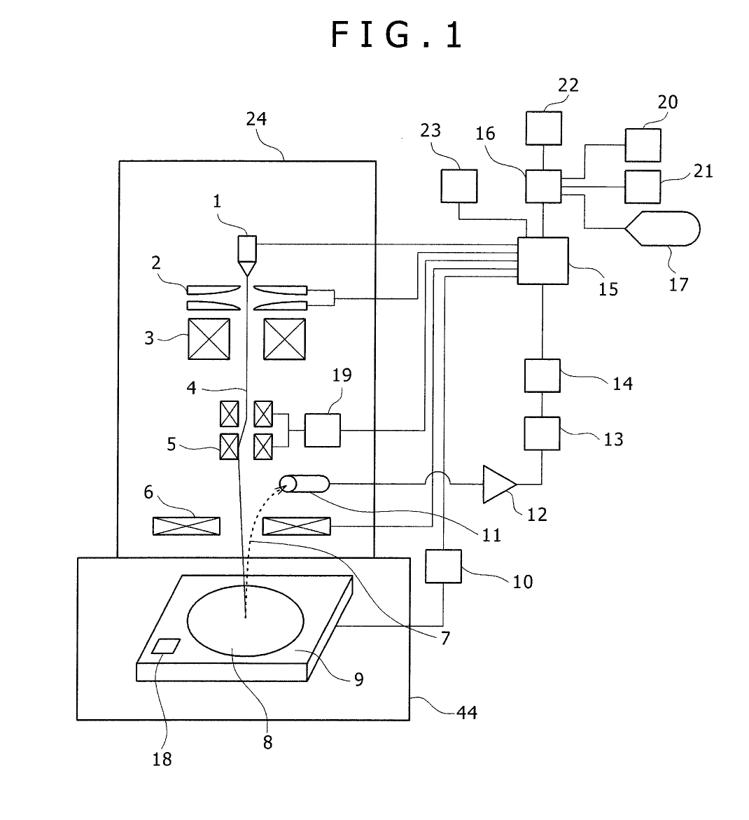

FIG. 1 is an explanatory diagram showing the entire configuration of a scanning electron microscope (referred to hereafter as an SEM) according to an embodiment. Roughly speaking, the SEM according to the embodiment is configured to comprise an electronic/optical system mirror cylinder 24, a sample chamber 44 and other control systems.

First of all, the electronic/optical system mirror cylinder 24 is explained as follows. A primary-electron beam 4 emitted by an electron gun 1 is directed to a sample 8 through an anode 2, a condenser lens 3 and an object lens 6. The anode 2 controls and accelerates the primary-electron beam 4 whereas the condenser lens 3 and the object lens 6 converge the primary-electron beam 4 and radiate the primary-electron beam 4 to the sample 8. The sample 8 such as a semiconductor wafer is held on a sample stage 9. On the sample 8, a pattern to be subjected to a length measurement has been created. On the path of the primary-electron beam 4, a deflector 5 has been provided. The deflector 5 receives a deflecting current determined in advance from a deflection controlling section 19 which supplies the current in accordance with a set magnifying power determined in advance. Thus, the primary-electron beam 4 is deflected and scans the surface of the sample 8 2-dimensionally. The electron beam is radiated to the sample 8, generating secondary electrons 7 which are detected by a secondary-electron detector 11. The detected secondary electrons 7 are amplified by an amplifier 12 and stored in an image storing section 13. Then, the stored image is used in a length measurement carried out by a length-measurement processing section 14. The length-measurement processing section 14 has a processor for carrying out processing determined in advance on the profile of an obtained image signal in order to find the dimensions of the pattern. The length-measurement processing section 14 reads out data of the image signal stored in the image storing section 13 in order to carry out the length measurement. In addition, the image signal obtained at that time is displayed on a display section 17.

The sample 8 is mounted on a sample base kept in the sample chamber 44. The sample base mounted on the sample stage 9 can be moved over an XY plane with a high degree of freedom. At the same time, a micro scale 18 is also mounted on the sample base. A length-measurement value found from an image at a length measurement point of the sample stage 9 is calibrated by making use of a standard scale value found from an image of the micro scale 18. The SEM is configured so that the visual-field movement of the SEM to a length measurement point is a movement to any arbitrary position that can be determined. The movement is made in accordance with an operation carried out by a stage controlling section 10 to control the sample stage 9.

A variety of operating conditions of the electronic/optical system mirror cylinder 24 are controlled by a control section 15. In addition, the control section 15 is connected to a computer 16 for playing a role as an SEM management console. A display section 17 displays a GUI screen used for setting the operating conditions of the electronic/optical system mirror cylinder 24. The apparatus user operates an input device connected to the computer 16 in order to set the operating conditions of the SEM on the GUI screen. Examples of the input device are a mouse 20 and a keyboard 21. The operations to set operating conditions of the SEM can also be carried out by making use of a dedicated operation panel 23 without setting the conditions on the GUI screen. A database (DB) 22 is stored in a secondary storage apparatus such as a nonvolatile memory or a hard disk. The DB 22 is used for keeping and managing information on the micro scale 18.

When carrying out a dimension calibration on a length-measurement value obtained from an SEM image, the micro scale 18 is moved to the inside of the visual field of the electronic/optical system mirror cylinder 24 in order to acquire an image of any cell on the micro scale 18. The dimension calibration of a length-measurement value is carried out by controlling the deflecting current and controlling the magnifying power of the length-measurement processing section 14. It is to be noted that, in place of the electronic/optical system mirror cylinder 24, the computer 16 can also be used for carrying out the length-measurement processing in some cases.

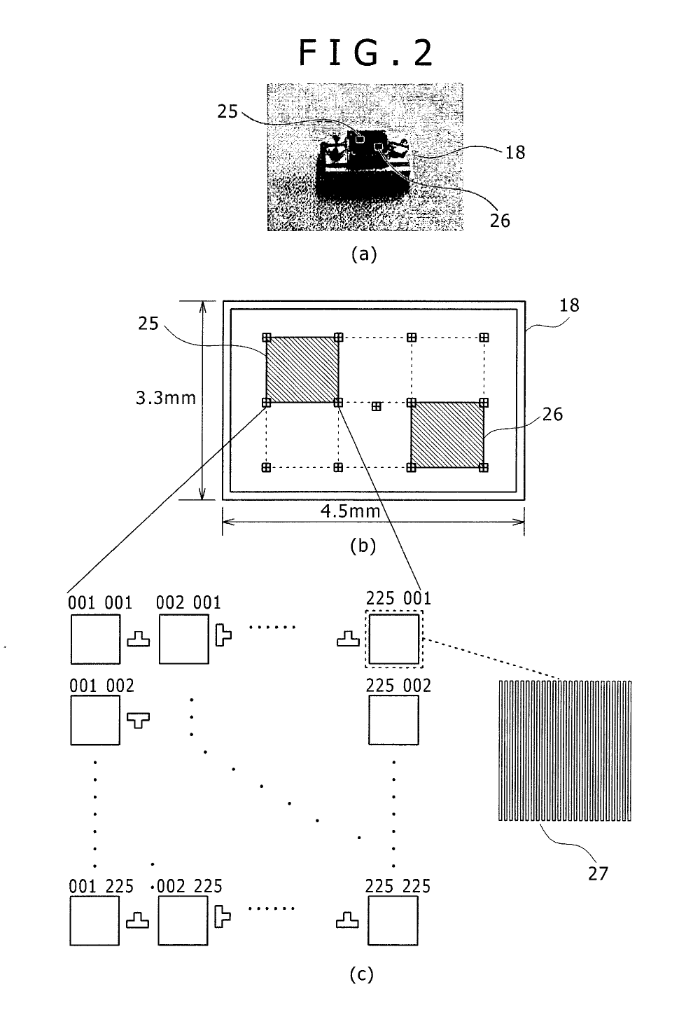

Next, FIG. 2 is given to serve as diagrams showing a typical configuration of the micro scale 18. To be more specific, FIG. 2(a) shows the external appearance of the micro scale 18 according to an embodiment. As shown in FIG. 2(a), in the micro scale 18 according to the embodiment, 2 grating pattern creation areas are created on a silicon substrate. FIG. 2(b) is a diagram showing the top surface of the micro scale 18 shown in FIG. 2(a). The orientation of a line and a space which are created in a specific one of the 2 grating pattern creation areas is perpendicular to the orientation of a line and a space which are created in the other one of the 2 grating pattern creation areas. Thus, by properly selecting one of the 2 grating pattern creation areas, it is possible to carry out the dimension calibration in the X or Y direction. In the following description, the grating pattern creation area denoted by reference numeral 25 is referred to as a longitudinal-direction grating pattern creation area whereas the grating pattern creation area denoted by reference numeral 26 is referred to as a lateral-direction grating pattern creation area.

FIG. 2 (c) is an enlarged diagram showing the longitudinal-direction grating pattern creation area 25. As described above, a line-and-space pattern used in the dimension calibration is collectively created in an area referred to as a cell. Then, a plurality of such cells are further laid out regularly to create the longitudinal-direction grating pattern creation area 25. Reference numeral 27 denotes an enlarged inside of the cell. As shown in FIG. 2(c), all the cells in the longitudinal-direction grating pattern creation area 25 are created by being oriented in the Y direction. On the contrary, all the cells in the lateral-direction grating pattern creation area 26 are created by being oriented in the X direction. In the case of this embodiment, cells are arranged inside the longitudinal-direction grating pattern creation area 25 to form 225 rows and 225 columns. That is to say, the cells are arranged inside the longitudinal-direction grating pattern creation area 25 to form a matrix consisting of 50,625 cells. Above each of the cells, a cell number assigned to the cell is shown. The cell number is a number determined by taking the left top cell in the grating pattern creation area as a reference point. The cell number assigned to the cell is used as the cell address in management of cells inside the longitudinal-direction grating pattern creation area 25 or the lateral-direction grating pattern creation area 26.

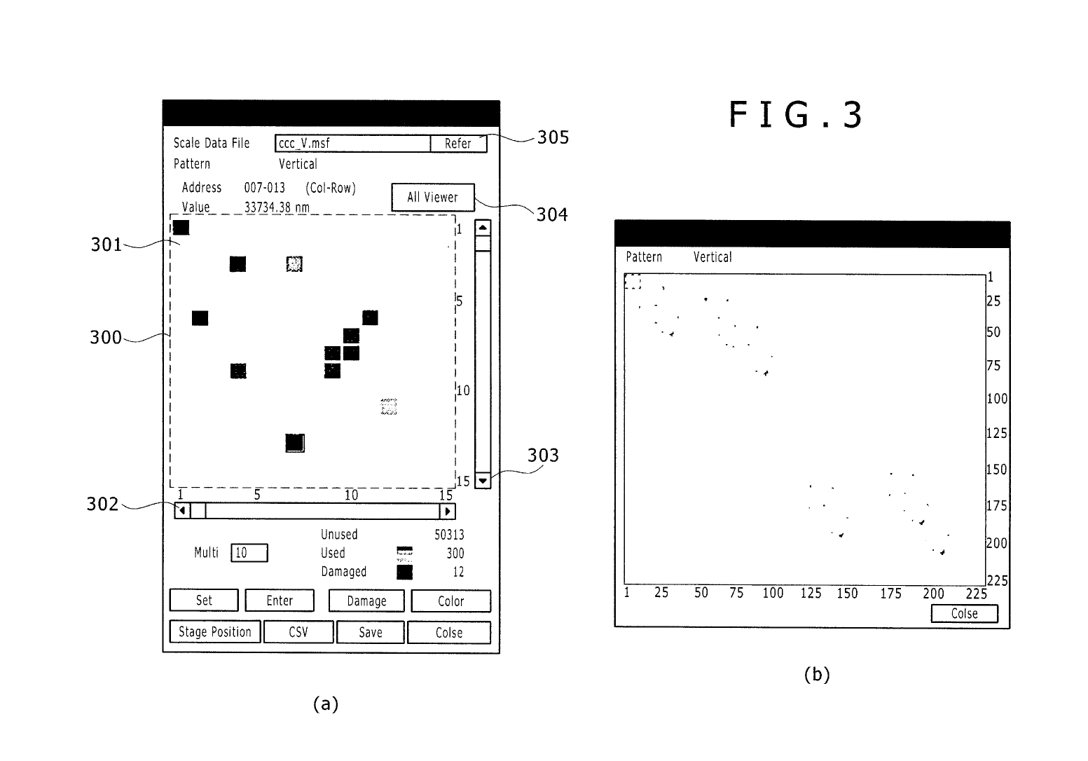

FIG. 3(a) shows a typical configuration of a micro scale management map displayed on a GUI screen of a SEM according to an embodiment. The map shown in FIG. 3(a) has a cell displaying area 300 enclosed by a dashed line in the diagram. The cell displaying area 300 displays some of the cells created in the grating pattern creation area. In the example shown in FIG. 3(a), some of the cells created in the longitudinal-direction grating pattern creation area 25 shown in FIG. 2(c) are displayed. The cells displayed in this example have cell addresses (001, 001) to (015, 015). Each of the cells displayed in the cell displaying area 300 has a rectangular shape. For example, a cell 301 has a cell address (001, 002) which is one of the cell addresses assigned to the cells shown in FIG. 2(b).

If a cell shown on the map is clicked, the visual field of the SEM is moved to the clicked cell. This function can be implemented as follows. The computer 16 computes a movement distance of the stage by making use of the configuration of cells laid out on the micro scale by being separated laterally and longitudinally from each other by equal distances and supplies the computed movement distance to the stage controlling section 10 by way of the control section 15. In addition, there is also provided another function. In accordance with this other function, while the stage is being moved, the deflector 5 or a blanking detector shown in none of the figures avoids radiation of an electron beam to the micro scale in order to prevent the micro scale from being damaged.

By operating an X scroll bar 302 or a Y scroll bar 303, a sequential display area used for displaying cells can be shifted from one to another in the cell displaying area 300. In addition, by clicking an ALL viewer button 304, as shown in FIG. 3 (b), all cells in the grating pattern creation area can also be displayed in the cell displaying area 300. A reference button 305 is a button for reading in a management file of cells.

In this embodiment, cells displayed on the map are laid out to form 15 rows and 15 columns. However, the number of cells displayed on the map can be set arbitrarily. The number of cells displayed on the map is set by taking the visibility and the operability into consideration.

The micro scale management GUI according to this embodiment has a function for displaying the states of unused cells, used cells and damaged cells on the map in a condition that can be visually verified. The states of unused cells, used cells and damaged cells are displayed in a condition that can be visually verified by, for example, giving colors to the displayed cells. It is thus necessary to store the utilization state of every cell in the computer 16 or the database (DB) 22 in advance. The utilization state of a cell can be recognized by making use of one of the following 2 techniques, that is, a visual verification technique adopted by the apparatus user and an automatic determination technique implemented by a computer.

First of all, the visual verification technique adopted by the apparatus user is explained as follows.

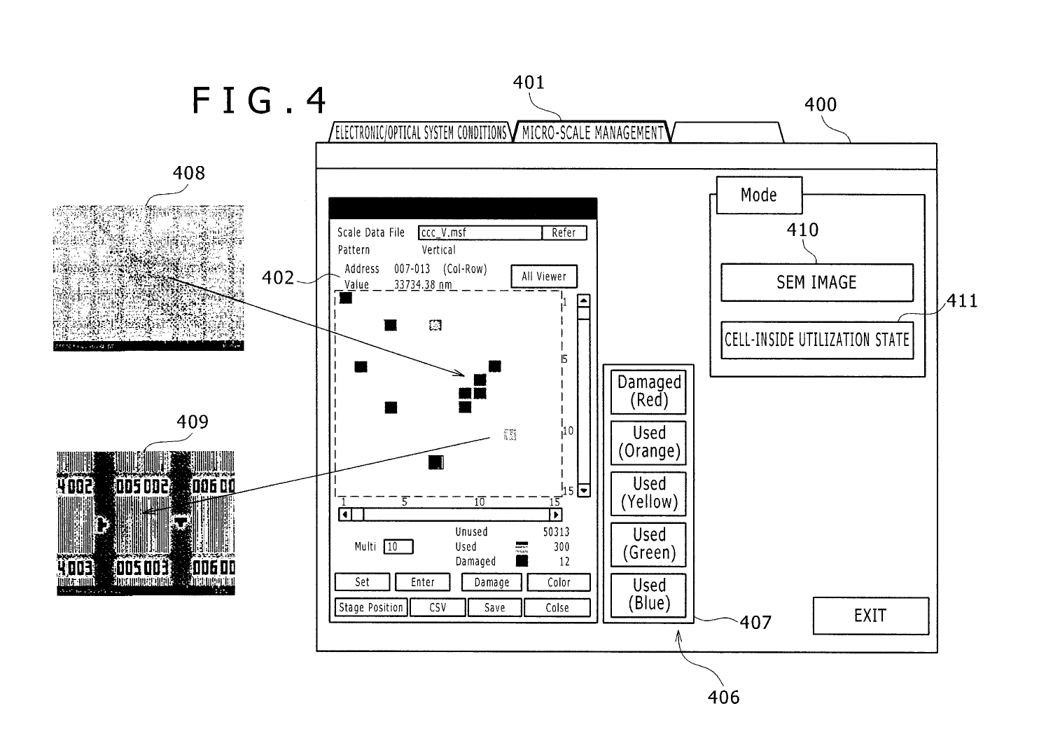

When it becomes necessary to record the state of a cell during a length measurement or an observation making use of the SEM, first of all, the apparatus user invokes the micro scale management GUI screen 400 shown in FIG. 4. To put it concretely, when the apparatus user clicks a tab 401 on the GUI, the micro scale management GUI screen 400 is activated.

The apparatus user double-clicks a cell on the map 402 or clicks the Stage Position button in order to move the stage to a desired cell. After a cell to be used has been determined, the cell at the corresponding address on the map 402 is selected on the map. When a Set button on the map 402 is clicked, a length measurement of a line pattern is started. (A length-measurement cursor is displayed and the position of the cursor is adjusted to the line pattern in order to carry out the measurement). After the measurement has been completed, the cell is included in a Used (Blue) category in order to leave a history of the execution of the measurement. For example, a cell included in a Used (Yellow) category indicates the fact that the cell at that position has been used 3 times.

In addition, the category classification can be carried out to manually categorize a damaged cell from category classification setting on a window 407 in addition to a Set button on the map 402.

A category button corresponding to a visually verified SEM image is clicked. In this embodiment, there are 5 category buttons, namely, Used (Blue) to Used (Orange) and Damaged (Red). A color enclosed in parentheses is information on a color assigned to a Damaged category. The color enclosed in parentheses corresponds to the color of a cell displayed on the map.

Information on the Damaged category set by a clicking operation is stored in a management table by way of the computer 16. For example, a cell shown by an SEM image 408 is clearly a damaged cell and classified as a cell pertaining to the Damaged (Red) category. In this case, the cell at the position is treated as Damaged (Red). In addition, a partially usable area also exists in a cell shown by an SEM image 409. Since burning caused by an electron radiation has occurred and the cell is closed to Damaged (Red), however, the cell is classified as a cell pertaining to the Damaged (Orange) category. In addition, the Used categories include Used (Blue)→Used (Green)→Used (Yellow)→Used (Orange) which are put in a sequence starting with the Used (Blue) category having a lowest degree of damage. The utilization state of a cell can thus be classified as a cell pertaining to one of these categories. An unused cell is given a white color. Thus, in an initial state, all cells have a white color.

A Color button on the map 402 is a button for changing the number of categories from 3 to 6. The 3 categories are Used (Blue), Damaged (Red) and the white color. These categories are used to classify a cell so that it is possible to easily determine whether or not the cell has been used. That is to say, if a cell has been used, the cell is classified as a cell pertaining to the Used (Blue) category. If a cell has been damaged, the cell is classified as a cell pertaining to the Damaged (Red) category. If a cell has not been used, the cell is classified as a cell pertaining to the white-color category. The 6 categories are 5 categories and the white-color category for unused cells. The 5 categories are the Used (Blue) category described above, the Damaged (Red) category described above and 3 newly added categories which are provided between Used (Blue) and Damaged (Red).

For example, for a user always making use of a cell only once and not utilizing the same cell anymore, the 6 categories should not be required. That is to say, for such a user, only the 3 categories are needed. For a user making use of a cell a plurality of times, on the other hand, it is necessary to provide information indicating the number of times a cell has been used and information indicating that a cell has been damaged. To such a user, the 6 categories are recommended.

In addition, CSV and Save buttons on the map 402 are buttons used for saving management data on the map. If it is desired to save data of a CSV format, the CSV button is clicked. The saved data includes data related to length measurement and length-measurement conditions (electron optical system conditions). The data related to length measurement includes a length-measurement address, the number of utilizations and a length-measurement value. On the other hand, the length-measurement conditions include an acceleration voltage, a magnifying power and information on a detector.

If it is desired to save only management data (map data having the extension ‘mev’), on the other hand, the Save button is clicked.

As described above, the utilization states of cells are classified into a plurality of categories in accordance with the damage state so that, unlike the conventional simple operation which simply prevents a cell from being used a plurality of times exceeding a predetermined number of times, the utilization count management for every cell can be carried out more finely than the conventional method. In addition, since the utilization state of every cell can be grasped visually, the operability is enhanced.

Next, automatic determination methods are explained. The automatic determination methods is a method adopted by the computer 16 to determine the state of damage from an SEM image of a cell on the basis of a determination reference determined in advance. Typical automatic determination methods are described as follows.

(1): Method for Determining the State of Damage by Comparing a Length-Measurement Result of a Micro Scale with Specification Values of a Grating Pattern Pitch

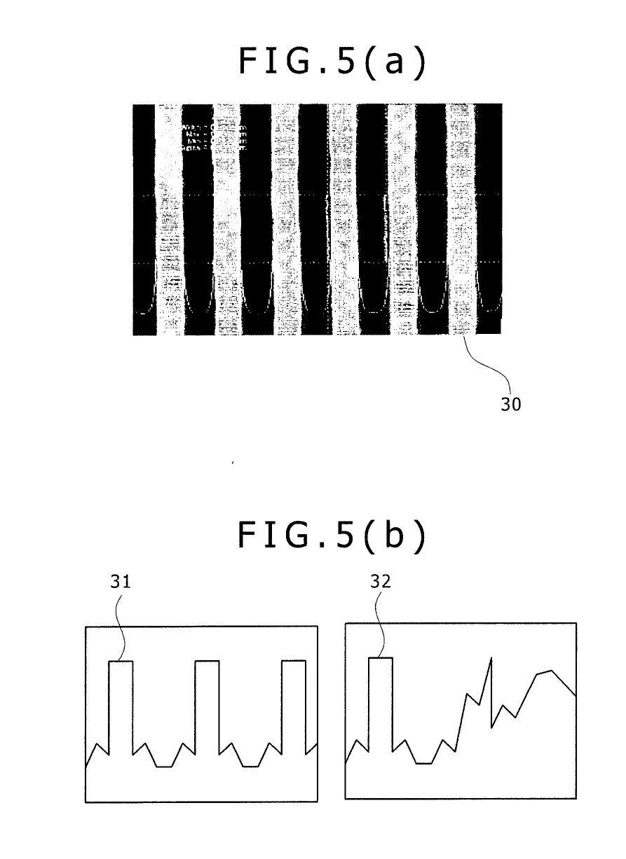

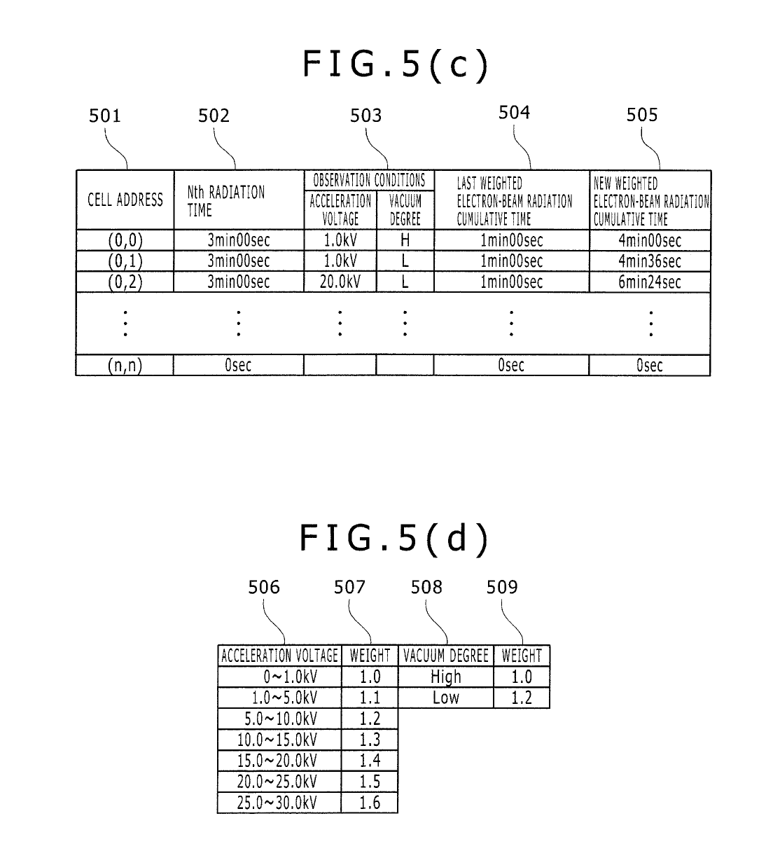

In accordance with this method, an SEM image of a micro scale is taken and, from the taken SEM image, the pattern pitch of the micro scale is found. Then, the found pitch value is compared with specification values and, if a result of the comparison indicates that the pitch value is beyond the specification values, the cell is determined to be a used or damaged cell. In the case of this embodiment, the specification values of the pitch of the micro scale are in a range of 100±1.2 nm. If the obtained pattern pitch is beyond the range of 100±1.2 nm, the computer 16 determines that the cell is a used or damaged cell. In this case, the color on the management map is changed. FIG. 5(a) shows a typical GUI display showing a taken SEM image and a line profile superposed thereon.

### (2): Method for Determining the State of Damage by Comparing Line Profiles Composing an SEM Image

With the pattern on the micro scale being a line-and-space pattern, an image signal obtained by detecting electrons ranging from secondary electrons to reflected electrons basically has a standard profile 31. Thus, a line profile obtained by taking an image of the undamaged micro scale is stored in advance in a memory included in the computer 16 as the standard profile 31 to be compared with a line profile obtained by taking an image of a cell, the damage state of which is to be examined. If a result of the comparison indicates that the line profile is much different from the state of the standard profile 31, (that is, if the result of the comparison indicates that the obtained pattern pitch is beyond the micro-scale specification-pitch range of 100±1.2 nm for example), the result of the comparison leads to determination that dirt or a foreign substance has been attached to the cell or the line pitch has been damaged. In this case, the cell is determined to be a damaged cell. FIG. 5(b) is a model diagram showing a standard profile and a typical profile of a damaged cell.

### (3): Method for Managing Cumulative Times of Electron-Beam Radiation to 1 Cell

In accordance with this method, an upper limit (such as 10 minutes per cell) of times of electron-beam radiations to cells is determined in advance. (For example, the upper limit is set at 10 minutes per cell). If an electron beam has been radiated to a cell for a time period longer than the upper limit, the cell is regarded as a damaged cell. Thus, the computer 16 stores a cumulative time of an electron-beam radiation to every cell in advance by associating the cumulative time with the address of the cell and, every time a cell is used, the stored cumulative time is updated. Typically, the cumulative time recorded for a cell is associated with the address of the cell in a table saved in a memory to serve as a table used for storing the cumulative time and the address.

In addition, the degree to which the micro scale is damaged varies, depending on observation conditions set for the SEM. For example, if the acceleration voltage is high, the micro scale can be damaged by a short-time radiation of an electron beam. If the acceleration voltage is low, on the other hand, the micro scale may not be damaged that much even by a long-time radiation of an electron beam. In other conditions, in the case of observation at a low degree of vacuum, the micro scale can be damaged by a short-time radiation of an electron beam. In the case of observation at a high degree of vacuum, on the other hand, the micro scale may not be damaged that much even by a long-time radiation of an electron beam. For the reasons described above, a threshold value used for determining a damage state is changed in accordance the observation conditions. As an alternative, at the computation time of the cumulative time of the electron-beam radiation, the cumulative time is computed by making use of weights determined by the observation conditions.

FIGS. 5(c) and 5(d) show typical configurations of management tables used for computing cumulative times by making use of weights according to observation conditions. To be more specific, FIG. 5(c) shows a cumulative-time management table used for managing cumulative times by associating the cumulative times with observation conditions. The cumulative-time management table comprises an address field 501 used for storing cell addresses, an electron-beam radiation time field 502 used for storing electron-beam radiation times at the present image taking time, an observation-condition field 503 used for storing observation conditions such as the acceleration voltage value and the degree of vacuum, a cumulative-time field 1 used for storing weighted electron-beam radiation cumulative times computed for the immediately preceding image taking time by making use of weights and a cumulative-time field 2 used for storing weighted electron-beam radiation cumulative times computed for the present image taking time by multiplying the radiation times stored in the electron-beam radiation time field 502 by a variety of weights.

FIG. 5(d) shows an observation-condition table used for storing observation conditions and weights for the observation conditions. In the case of this embodiment, the observation-condition table comprises an acceleration-voltage field 506, a weight field 507 for the acceleration-voltage field 506, a vacuum-degree field 508, a weight field 509 for the vacuum-degree field 508. The tables shown in FIGS. 5(c) and 5(d) are stored in the database (DB) 22 or a memory employed in the computer 16.

At an image taking time of the micro scale, the computer 16 receives a set scan count of a primary electron beam and a set scan deflection frequency of the beam from the control section 15, computing a time of an electron-beam radiation to a cell, the image of which is taken. At the same time, the computer 16 also receives information on the acceleration voltage and a set vacuum degree from the control section 15. This information is used for updating the fields of the management table shown in FIG. 5(c). In addition, the computer 16 reads out the observation-condition table shown in FIG. 5(d) and makes use of a weight corresponding to the observation conditions as a coefficient to be multiplied by a value stored in the electron-beam radiation time field 502 to result in a product. Subsequently, the product is added to a value stored in the cumulative-time field 1 to give a sum which is then stored in the cumulative-time field 2.

For example, the weighted electron-beam cumulative time for an address of (0, 0) is explained as follows. For the address of (0, 0), the value stored in the electron-beam radiation time field 502 is 3 min and 00 sec, the acceleration voltage is 1.0 kV and the vacuum degree is H. Since the weights for the acceleration voltage of 1.0 kV and the vacuum degree of H are 1.0 and 1.0, these weights are multiplied by the value stored in the electron-beam radiation time field 502 to give a product which is then added to the value of 1 min and 00 sec stored in the cumulative-time field 1 to give a sum of 4 min and 00 sec. (The sum is then stored in the cumulative-time field 2). The operations described above are represented by an equation given as follows:

3 min and 00 sec×1.0×1.0+1 min and 00 sec=4 min and 00 sec

By the same token, operations for an address of (0, 2) are represented by an equation given as follows:

3 min and 00 sec×1.5×1.2+1 min and 00 sec=6.4 min=6 min and 24 sec

It is to be noted that a step size can also be set arbitrarily for an observation condition. For example, in the case of this embodiment, the vacuum degree is set at 2 levels, that is, the H (high) and L (low) levels. However, the vacuum degree can also be set more finely at more levels. In addition, besides the acceleration voltage and the vacuum degree, another observation condition such as a beam current value can also be added to the acceleration voltage and the vacuum degree. On the top of that, it is also possible to set upper and lower limits and the step size for an observation condition. In addition, it is also possible to arbitrarily set a weight for each level of an observation condition. Furthermore, in the case of this embodiment, the electron-beam radiation time is managed by making use of 2 tables, that is, the cumulative time management table and the observation-condition table. However, the 2 tables can also be integrated into 1 table used for managing the electron-beam radiation time.

In accordance with the technique described above, the damage state of a cell for a radiation time is recognized by giving a color indicating the damage state to the cell. Thus, in comparison with other techniques, the technique described above offers a merit of allowing damage categories to be set more finely. In accordance with the technique for displaying cells on a map in different colors, manual setting operations are carried out on a GUI explained before by referring to FIG. 4.

When the automatic determination described above is carried out, it is not only possible to display cells in different colors, but also possible to give a notice such as a message to the user. In addition, a variety of conditions are managed by making use of a database. On the top of that, the computer 16 according to this embodiment is also provided with a number management function for managing the displays of utilization states of cells such as an unused cell, a used cell and a damaged cell. This function informs the user of a number which is the number of executable cell utilizations (that is, the number of times a cell can be used hereafter) or a usability rate. In addition, the function also gives a warning such as a message to the user when the number of remaining usable cells becomes small. (For example, the message requests the user to replace the current micro scale with a new one).

As described above, this embodiment makes it possible to implement a scanning electron microscope capable of visually displaying the utilization states of cells on a micro scale.

### Second Embodiment

This embodiment is used for explaining a typical configuration of a scanning electron microscope capable of managing cell utilization states in the same cell. Since the entire configuration of this apparatus is about identical with the first embodiment, explanations of identical portions are omitted. In addition, the explanation of this embodiment properly refers to FIG. 1.

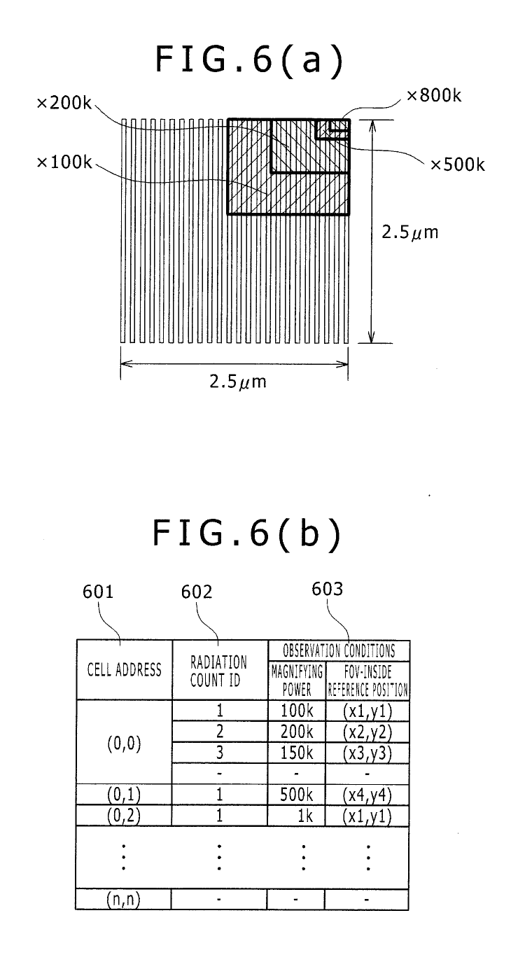

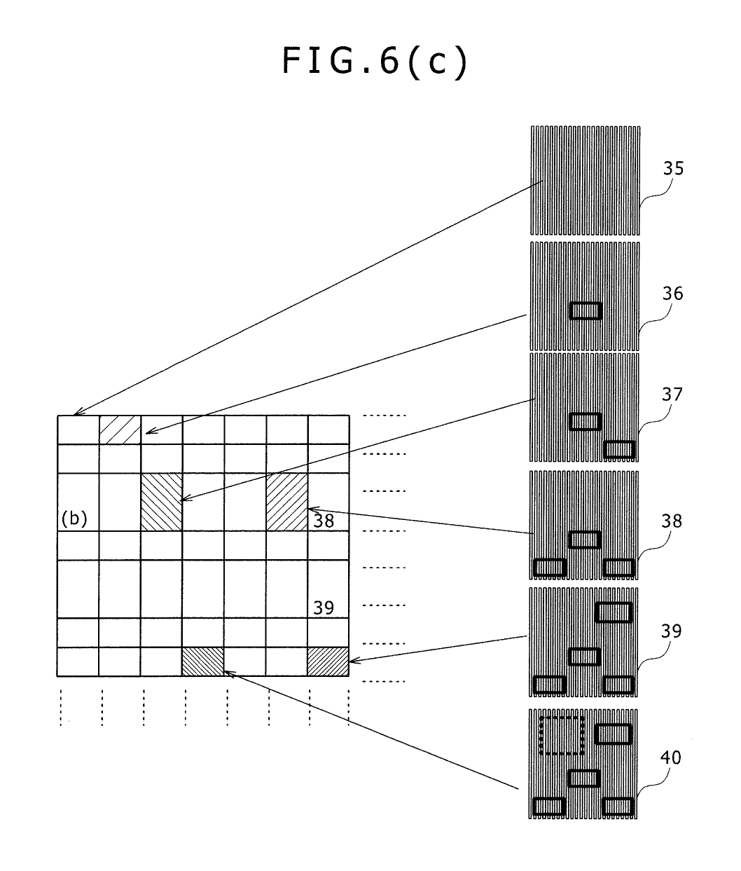

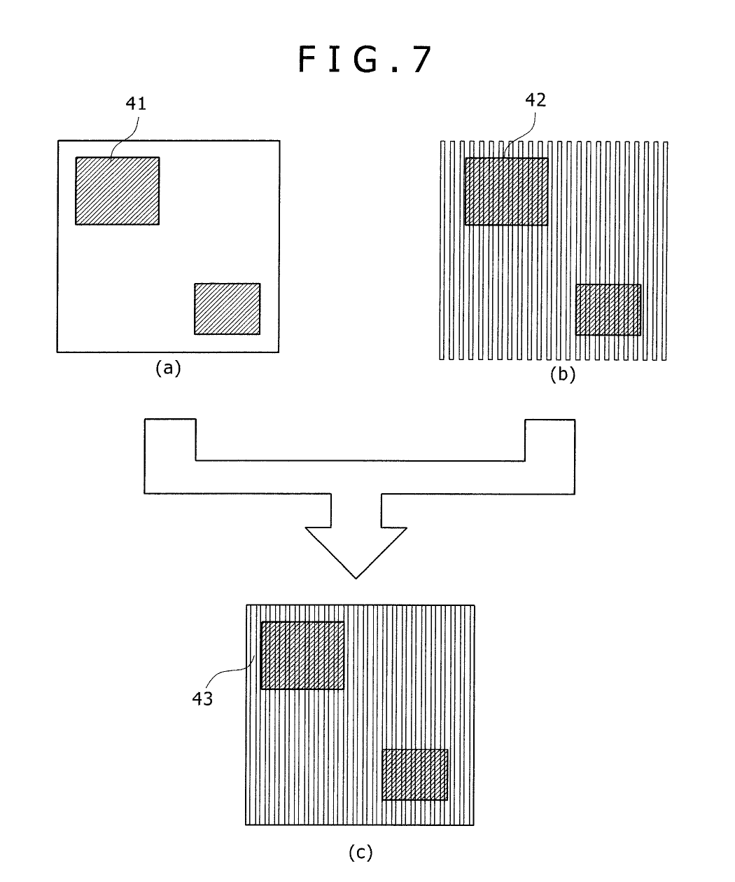

In the case of an SEM, the magnifying power changes the radiation area of an electron beam. For example, in the case of a large magnifying power, the FOV (Field of View) size decreases so that the usable area in the same cell increases. In the case of a small magnifying power, on the contrary, the FOV (Field of View) size increases so that the usable area in the same cell decreases. In FIG. 6(a), a height of 2.5 microns and a width of 2.5 microns are dimensions of a cell in a micro scale. The figure shows that, when the magnifying power increases from 100 k to 800 k through 200 k and 500 k, the size of the electron-beam radiation area in the cell decreases.

Once the size of the primary electron-beam radiation area for a reference magnifying power has been determined, the FOV size changes only in accordance with the magnifying power. As an example, the reference magnifying power of the SEM is set at 1. The following description explains a case in which the FOV size at this magnifying power is set for a Polaroid camera use. (In the case of a Polaroid camera, the width is 127 mm whereas the height is 96.3 mm). Since the dimensions of the FOV size for the reference magnifying power×1 time are 127 mm×96.3 mm, for the reference magnifying power×1,000 k times, the dimensions are 127 mm/1000 k×96.3 mm/1000 k=127 nm×96.3 nm. By the same token, in the case of 500 k, the dimensions are 254 nm×192.6 nm. Thus, if the FOV size at the reference magnifying power and the magnifying power are known, the size of the primary electron-beam radiation area can be computed.

In order to identify a radiation position in a cell, on the other hand, the coordinates of a proper reference position in the FOV are required. In many cases, this reference position is set at the center of the FOV or the left upper corner of the FOV. The left upper corner of the FOV is a corner serving as a position from which the radiation of an electron beam is started. Normally, the coordinates of the reference position are held in the stage controlling section 10.

Thus, this embodiment is provided with a management table used for managing the number of image taking operations of each cell in the micro scale, its image taking magnifying power and information on the reference position in the FOV. Therefore, it is possible to visually display historical information on the primary electron-beam radiation area in an identified cell.

FIG. 6(b) shows a typical configuration of a table used for managing radiation areas in a cell. The management table is configured to include a cell-address field 601 used for storing cell addresses, a radiation-count ID field 602 used for storing numbers each serving as the number of times radiation is carried out and an observation-condition field 603 used for storing magnifying powers and coordinates of a reference position in each FOV.

FIG. 6(c) shows typical utilization states of a cell displayed on a GUI. When the apparatus user invokes a micro-scale management GUI shown in FIG. 4, clicks a cell inside utilization state button 411 and further clicks any arbitrary cell on the map 402, the apparatus user is capable of identifying which portions of the cell have been used. The computer 16 refers to the management table shown in FIG. 6(b) in order to compute an electron-beam radiation area for every radiation-count ID by making use of the magnifying powers in the clicked cell, the FOV size at the set reference magnifying power and the coordinates of the reference position in the FOV. The computed areas and frame lines each showing the external shape of one of the areas are displayed by being superposed on each other on a model diagram of the cell.

FIG. 6(c) is a model diagram showing the information described above. This figure shows an example in which 5 portions in the same cell have been used. On the cell map, the cell is displayed in a color indicating the number of times the cell has been used. In this example, the cell is displayed in 6 different colors as follows. At the initial state, the cell is displayed in a white color 35. Then, after the cell has been used once, the cell is displayed in a blue color 36. Subsequently, after the cell has been used twice, the cell is displayed in a green color 37. Then, after the cell has been used 3 times, the cell is displayed in a yellow color 38. Subsequently, after the cell has been used 4 times, the cell is displayed in an orange color 39. Finally, after the cell has been used 5 times, the cell is displayed in a red color 40. In addition, right after the 5 length measurements have been carried out, the cell can be displayed in a damage color (a red color) in order to indicate that the cell can no longer be used (It is assumed that there is a risk that a subsequent length measurement may be carried out on an overlapping length-measurement area).

By providing the configuration described above, it is possible to manage usable areas in 1 cell and also possible to make use of the same cell a plurality of times.

When acquiring an SEM image of the micro scale, on the other hand, if the same cell has been subsequently used a plurality of times, in order to disallow an area (a line pattern) used previously to be reused, the used area (stage coordinates, the observation magnifying power and the like) is stored. If an SEM image of the used area has been displayed on a CRT, the frame of the used area can be superposed on the display area of the SEM image. The frame of the used area can be a simple or colored frame superposed thereon.

By referring to FIG. 7, the following description explains a method for displaying the frame of a used area. The method for displaying the frame of a used area can be a method, in accordance with which, the frame of a used area is computed from the stage coordinates (that is, the X, Y and R axes. In some cases, the T axis serving as an inclination axis and the Z axis oriented in the height direction may be added) and the observation magnifying power and, then, the computed frame is displayed. As an alternative, the method for displaying the frame of a used area can also be a method of creating a template of a used area in advance when making use of the micro scale.

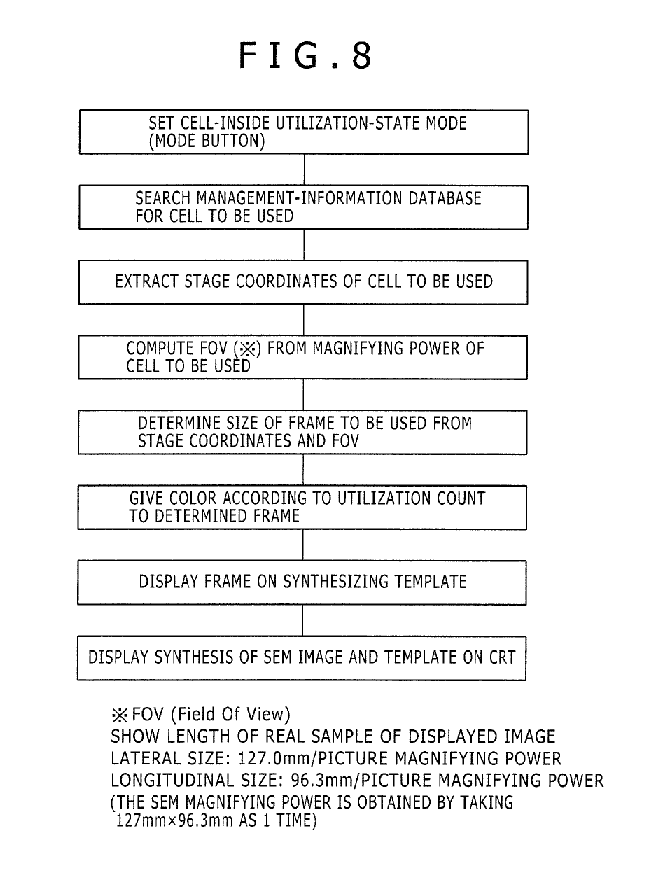

FIG. 8 is a diagram referred to in explanation of the latter method of creating a template. This function is carried out to create an image synthesizing template 41 when making use of a micro scale and store stage coordinates in a DB. Later on, if a used area 42 has been displayed on a CRT (The stage coordinates and the magnifying power are used in determining whether or not the used area 42 has been displayed on the CRT), the template is synthesized with an upper portion of a cell image in order to display an area experiencing a length measurement in the past on the CRT as a color display 43.

It is to be noted that, even if a magnifying power different from that of the length measurement is displayed, the image synthesizing template 41 can be displayed by being enlarged or contracted in accordance with a magnifying power link.

As described above, if a used area has been displayed, the used area is typically put in a color display or a frame display and, by making the previous length measurement area visible, it is possible to avoid a length measurement carried out at the same portion.

FIG. 8 is a flowchart showing a template creation procedure.

### Third Embodiment

If a plurality of micro scales are used, a plurality of DBs exist. Any one of the DBs can be selected manually. However, there is provided a function for extracting a desired management DB automatically by making use of a means described as follows.

The automatic extraction method can be a method of detecting the states of all cells (by carrying out an electron-beam scanning operation) and comparing the utilization states (the states of an unused cell, a used cell and a damaged cell) with the contents of a DB in order to determine whether or not they match each other. In this case, however, it inevitably takes long time to carry out the processing to detect the states of all cells. In addition, from the standpoint of preventing cells from being damaged, this method is also undesirable. For these reasons, a certain point (or a certain area) is detected and compared with the contents of the DB in order to determine whether or not they match each other. If some points match the contents of the DB, the DB is determined and the user is informed of the contents of the DB. This function is a function effective for a case in which a plurality of micro scales are used. This function is also a function effective for a case in which a plurality of apparatus exist provided that a DB has been copied to each of the apparatus in advance.

### DESCRIPTION OF REFERENCE NUMERALS

1: Electron gun
2: Anode
3: Condenser lens
4: Primary electron beam
5: Deflector
6: Object lens
7: Secondary electrons
8: Sample
9: Sample stage
10: Stage controlling section
11: Secondary-electron detector
12: Amplifier
13: Image storing section
14: Length-measurement processing section
15: Control section
16: Computer
17: Display section
18: Micro scale
19: Deflection controlling section
20: Mouse
21: Keyboard
22: Database (DB)
23: Dedicated operation panel
24: Electronic/optical-system mirror cylinder
25: Longitudinal-direction line-pattern area
26: Transversal-direction line-pattern area
27: Line pattern
28: Damaged-cell image
29: Post-length-measurement contamination image
30: Line waveform and length-measurement value
31: Standard profile
32: Irregular line waveform
33: Cell utilization state ALL display menu
34: Damaged-cell numerical management
35: White (Unused)
36: Blue (First use)
37: Green (Second use)
38: Yellow (Third use)
39: Orange (Fourth use)
40: Red (Fifth use)
41: Image synthesizing template
42: Used area
43: Color display

1. A charged-particle beam apparatus comprising:
a scanning electron microscope for taking an electron-microscope image of a sample mounted on a sample stage by scanning the sample by making use of a primary-electron beam;
a dimension-calibration member placed on the sample stage and provided with a plurality of cells on each of which an uneven pattern for dimension calibration has been created;
a display section for displaying the electron-microscope image; and
an information processing means for managing primary-electron-beam scanning counts which are each the number of operations to scan one of the cells by making use of the primary-electron beam,
wherein the display section displays a GUI screen including:
a cell map showing a layout of the cells on the dimension-calibration member; and
information used for visually showing the primary-electron-beam scanning count for each of the cells.

2. A charged-particle beam apparatus according to claim 1,
wherein the cells are displayed on the cell map in different colors each indicating the number of operations to scan one of the cells by making use of the primary-electron beam.

3. A charged-particle beam apparatus according to claim 2 wherein:
in accordance with the primary-electron-beam scanning counts, the cells displayed on the cell map are classified into 3 categories, that is, a category of un-scanned ones of the cells, a category of the cells each having the primary-electron-beam scanning count smaller than a predetermined value and a category of the cells each having the primary-electron-beam scanning count equal to or greater than the predetermined value; and
the cells on the cell map are displayed in different colors each provided for one of the categories.

4. A charged-particle beam apparatus according to claim 1,
wherein the GUI screen displays:
cell counts which are each the number of the cells each having the primary-electron-beam scanning count equal to or greater than a predetermined value; or
fractions which are each a ratio of the number of the cells each having the primary-electron-beam scanning count equal to or greater than the predetermined value to the total number of the cells created on the dimension-calibration member.

5. A charged-particle beam apparatus according to claim 1,
wherein the GUI screen displays:
a scanning electron microscope image of a particular one of the cells on the dimension calibration member; and
visual information showing areas which each exist on the particular cell and have the primary-electron-beam scanning count greater than a predetermined value.

6. A charged-particle beam apparatus according to claim 1, wherein:
the scanning electron microscope acquires a scanning electron microscope image of a specified cell on the GUI screen displayed on the display section; and
the information processing means computes dimensions of an uneven pattern on the basis of the scanning electron microscope image of the specified cell and, if the computed dimensions are beyond specification values, the information processing means displays information on the display section to indicate that the computed dimensions are beyond the specification values.

7. A charged-particle beam apparatus according to claim 1,
wherein the information processing means stores a cumulative radiation time of the primary-electron beam for each of the cells and, if the cumulative radiation time is beyond prescribed values, the information processing means displays information on the display section to indicate that the cumulative radiation time is beyond the prescribed values.

8. A charged-particle beam apparatus according to claim 1,
wherein the scanning electron microscope moves a visual field so as to put a specified cell on the cell map in the area of the visual field.

9. A charged-particle beam apparatus according to claim 1,
wherein, in an operation carried out to move a visual field when taking an image of the dimension calibration member, the scanning electron microscope puts the primary-electron beam in a blanking state.
